(19) United States
(12) Patent Application Publication
(10) Pub. No.: US 2006/0180084 A1
(43) Pub. Date: Aug. 17, 2006

(54) Substrate susceptor for receiving a substrate to be deposited upon

(76) Inventors: Eric R. Blomiley, Boise, ID (US); Joel A. Drewes, Boise, ID (US); Nirmal Ramaswamy, Boise, ID (US); Ross S. Dando, Nampa, ID (US)

Correspondence Address: WELLS ST. JOHN P.S., 601 W. FIRST AVENUE, SUITE 1300, SPOKANE, WA, 99201, US

(21) Appl. No.: 11/399,888

(22) Filed: Apr. 7, 2006

Related U.S. Application Data
(62) Division of application No. 10/816,691, filed on Apr. 1, 2004.

(51) Int. Cl. C23F 1/00; C23C 16/00

(52) U.S. Cl. 118/725; 156/345.52

(57) ABSTRACT

This invention includes substrate susceptors which receive substrates to be deposited upon. In one implementation, a substrate susceptor includes a body having a substrate receiving side. The substrate receiving side has a face having a substrate receiving recess formed therein. The recess has an outer peripheral sidewall. At least three projections extend outwardly from a portion of the face. The projections respectively comprise a radially inner sidewall which extends outwardly from the recess outer peripheral sidewall to a projection upper surface. Other aspects and implementations are contemplated.

### RELATED PATENT DATA

This patent resulted from a divisional application of U.S. patent application Ser. No. 10/816,691, filed Apr. 1, 2004, entitled “Substrate Susceptor for Receiving a Substrate to be Deposited Upon”, naming Eric R. Blomiley, Joel A. Drewes, D. V. Nirmal Ramaswamy and Ross S. Dando as inventors, the disclosure of which is incorporated by reference.

### TECHNICAL FIELD

This invention relates to substrate susceptors which receive substrates to be deposited upon.

### BACKGROUND OF THE INVENTION

Integrated circuitry fabrication includes deposition of material and layers over a substrate. One or more substrates are received within a deposition chamber within which deposition typically occurs. One or more precursors or substances are caused to flow to the substrate, typically as a vapor, to effect deposition of a layer over the substrate. A single substrate is typically positioned or supported for deposition by a susceptor. In the context of this document, a “susceptor” is any device which holds or supports at least one wafer within a chamber or environment for deposition. Deposition may occur by chemical vapor deposition, atomic layer deposition and/or by other means.

FIGS. 1 and 2 diagrammatically depict a prior art susceptor 10, and issues associated therewith which motivated some aspects of the invention. Susceptor 10 comprises a body 12 which receives a substrate 14 for deposition. Substrate 14 is received within a pocket or recess 16 of susceptor body 12 to elevationally and laterally retain substrate 14 in the desired position.

A particular exemplary system which motivated some aspects of the inventive susceptor designs herein was a lamp heated, thermal deposition system having front and back side radiant heating of the substrate and susceptor for attaining desired temperature during deposition. FIG. 2 depicts a thermal deposition system having at least two radiant heating sources for each side of susceptor 10. Depicted are front side and back side peripheral radiation emitting sources 18 and 20, respectively, and front side and back side radially inner radiation emitting sources 22 and 24, respectively. Incident radiation from sources 18, 20, 22 and 24 typically overlap one another on the susceptor and substrate, creating overlap areas 25. Such can cause an annular region of the substrate corresponding in position to overlap areas 25 to be hotter than other areas of the substrate not so overlapped. Further, the center and periphery of the substrate can be cooler than even the substrate area which is not overlapped due to less than complete or even exposure to the incident radiation.

The susceptor is typically caused to rotate during deposition, with deposition precursor gas flows occurring along arrows “A” from one edge of the wafer, over the wafer and to the opposite side where such is exhausted from the chamber. Arrow “B” depicts a typical H₂ gas curtain within the chamber proximate a slit valve through which the substrate is moved into and out of the chamber. A preheat ring (not shown) is typically received about the susceptor, and provides another heat source which heats the gas flowing within the deposition chamber to the wafer along arrows A and B. However even so, the periphery of the substrate proximate where arrows A and B indicate gas flowing to the substrate is cooler than the central portion and the right-depicted portion of the substrate where the gas exits.

Additionally, robotic arms are typically used to position substrate 14 within recess 16. Such positioning of substrate 14 does not always result in the substrate being positioned entirely within susceptor recess 16. Further, gas flow might dislodge the wafer such that it is received both within and without recess 16. Such can further result in temperature variation across the substrate and, regardless, result in less controlled or uniform deposition over substrate 14.

The above-described system can be used for silicon deposition, including amorphous, monocrystalline and polycrystalline silicon, as well as deposition of silicon mixed with other materials such as a Si—Ge composition in any of crystalline and amorphous forms. Certain aspects of the invention were motivated relative to issues associated with selective epitaxial silicon deposition. In such deposition, a substrate to be deposited upon includes outwardly exposed elemental silicon containing surfaces as well as surfaces not containing silicon in elemental form. During a selective epitaxial silicon deposition, the silicon will preferentially/selectively grow typically only over the silicon surfaces and not the non-silicon surfaces. In many instances, near infinite selectivity is attained, at least for the typical thickness levels at which the selective epitaxial silicon is deposited or grown.

An exemplary prior art method for depositing selective epitaxial silicon includes flows of dichlorosilane at from 50 sccm to 500 sccm, HCl at from 50 sccm to 300 sccm and H₂ at from 3 slm to 40 slm. An exemplary preferred temperature range is from 750° C. to 1,050° C., with 850° C. being a specific example. An exemplary pressure range is from 5 Torr to 100 Torr, with 30 Torr being a specific example. Certain aspects of the invention also encompass selective epitaxial silicon-comprising deposition using the just-described prior art process (preferred), as well as other existing or yet-to-be developed methods.

It would be desirable to develop improved susceptor designs which address the above-identified problems. However although some aspects of the invention were motivated from this perspective and in conjunction with the above-described reactor and susceptor designs, the invention is in no way so limited. The invention is only limited by the accompanying claims as literally worded, without interpretive or other limiting reference to the specification and drawings, and in accordance with the doctrine of equivalents.

### SUMMARY

The invention includes substrate susceptors which receive substrates to be deposited upon. In one implementation, a substrate susceptor includes a body having a substrate receiving side. The substrate receiving side has a face having a substrate receiving recess formed therein. The recess has an outer peripheral sidewall. At least three projections extend outwardly from a portion of the face. The projections respectively comprise a radially inner sidewall which extends outwardly from the recess outer peripheral sidewall to a projection upper surface.

In one implementation, a substrate susceptor for receiving a substrate to be deposited upon includes a body having a substrate receiving side. The substrate receiving side comprises a face. At least three projections extend outwardly from a portion of the face. The projections respectively comprise a radially inner substrate retaining sidewall which extends outwardly to a projection upper surface.

In one implementation, a substrate susceptor for receiving a substrate to be deposited upon by thermal deposition comprising back side radiant heating of the susceptor comprises a body having a front substrate receiving side and a back side. The front and back sides respectively comprise a face. The front side face has an inner area face over which the substrate to be deposited upon is to be received. The back side face comprises at least one radiation emission-lowering recess received opposite a portion of the front side inner area face over which the substrate to be deposited upon is to be received.

In one implementation, a substrate susceptor for receiving a substrate to be deposited upon by thermal deposition comprising susceptor heating comprises a body having a front substrate receiving side and a back side. The front side has an inner area and a peripheral area received about the inner area. The front side comprises an inner area face received within and smaller than the inner area. The inner area face has a central region and a peripheral region received about the central region. The front side inner area has a peripheral surface configured to at least in part support a substrate to be deposited upon proximate a periphery of said substrate to space said substrate from a portion of the front side inner area face. The front side inner area face comprises at least one central region projection extending to contact the substrate to be deposited upon.

In one implementation, a substrate susceptor for receiving a substrate to be deposited upon by thermal deposition comprising susceptor heating comprises a body having a front substrate receiving side and a back side. The front side has an inner area and a peripheral area received about the inner area. The front side comprises an inner area face received within and smaller than the inner area. The inner area face has a central region and a peripheral region received about the central region. The front side inner area has a peripheral surface configured to at least in part support a substrate to be deposited upon proximate a periphery of said substrate to space said substrate from a portion of the front side inner area face. The peripheral surface extends radially inward with at least a 20 mm radial length of the peripheral surface being positioned to contact a substrate to be deposited upon.

In one implementation, a substrate susceptor for receiving a substrate to be deposited upon by thermal deposition comprising susceptor heating comprises a body having a front substrate receiving side and a back side. The front side has an inner area and a peripheral area received about the inner area. The front side comprises an inner area face received within and smaller than the inner area. The inner area face has a central region and a peripheral region received about the central region. The front side inner area has a peripheral surface configured to at least in part support a substrate to be deposited upon proximate a periphery of said substrate to space said substrate from a portion of the front side inner area face. The front side inner area face comprises a plurality of projections within the inner area face peripheral region extending to contact the substrate to be deposited upon.

Other aspects and implementations are contemplated.

### BRIEF DESCRIPTION OF THE DRAWINGS

Preferred embodiments of the invention are described below with reference to the following accompanying drawings.

FIG. 1 is a top view of a prior art susceptor.

FIG. 2 is a diagrammatic section of the FIG. 1 susceptor taken through line 2-2 in FIG. 1.

FIG. 3 is a top view of a susceptor in accordance with an aspect of the invention.

FIG. 4 is a diagrammatic section taken through line 4-4 in FIG. 3.

FIG. 5 is an alternate embodiment susceptor to that shown by FIG. 4.

FIG. 6 is an alternate embodiment susceptor to that shown by FIG. 4.

FIG. 7 is an alternate embodiment susceptor to that shown by FIG. 4.

FIG. 8 is an alternate embodiment susceptor to that shown by FIG. 4.

FIG. 9 is a bottom view of another susceptor in accordance with an aspect of the invention.

FIG. 10 is a diagrammatic section taken through line 10-10 in FIG. 9.

FIG. 11 is an alternate embodiment susceptor to that shown by FIG. 10.

FIG. 12 is an alternate embodiment susceptor to that shown by FIG. 10.

FIG. 13 is an alternate embodiment susceptor to that shown by FIG. 10.

FIG. 14 is an alternate embodiment susceptor to that shown by FIG. 9.

FIG. 15 is a top view of another susceptor in accordance with an aspect of the invention.

FIG. 16 is a diagrammatic section taken through line 16-16 in FIG. 15.

FIG. 17 is an alternate embodiment susceptor to that shown by FIG. 15.

FIG. 18 is an alternate embodiment susceptor to that shown by FIG. 15.

FIG. 19 is an alternate embodiment susceptor to that shown by FIG. 15.

FIG. 20 is a top view of another susceptor in accordance with an aspect of the invention.

FIG. 21 is a diagrammatic section taken through line 21-21 in FIG. 20.

FIG. 22 is an alternate embodiment susceptor to that shown by FIG. 21.

FIG. 23 is a diagrammatic section taken through line 23-23 in FIG. 24 of another susceptor in accordance with an aspect of the invention.

FIG. 24 is a top view of the susceptor of FIG. 23.

FIG. 25 is an alternate embodiment susceptor to that shown by FIG. 23.

FIG. 26 is an alternate embodiment susceptor to that shown by FIG. 23.

FIG. 27 is an alternate embodiment susceptor to that shown by FIG. 24.

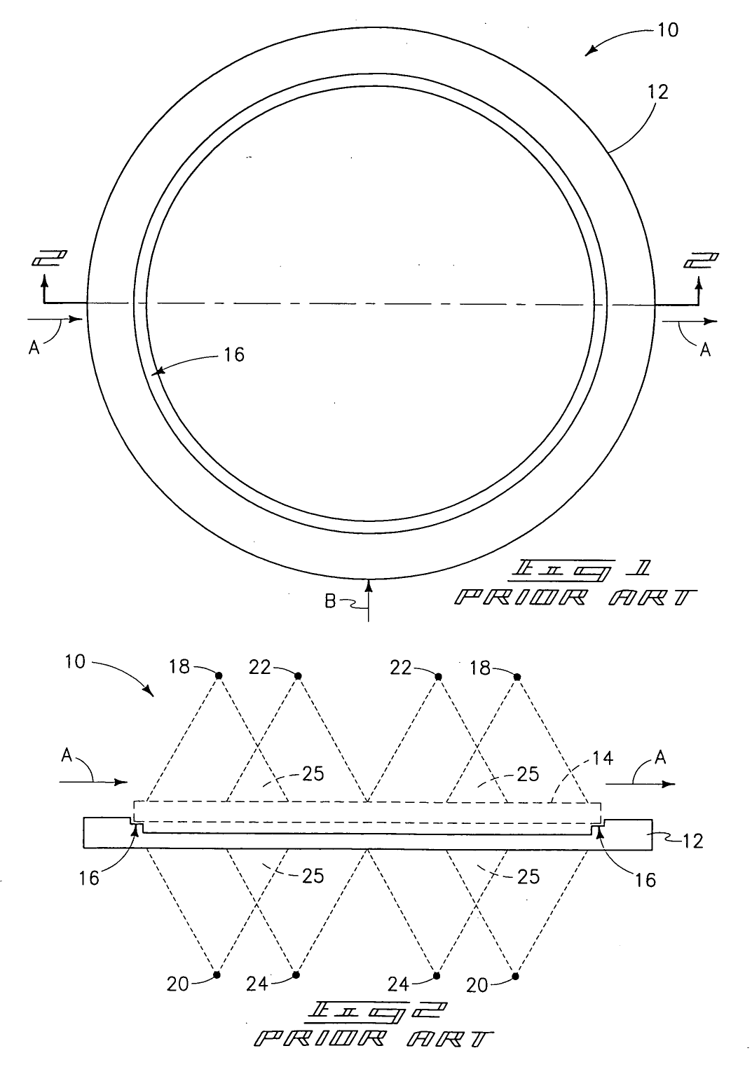

### DETAILED DESCRIPTION OF THE PREFERRED EMBODIMENTS

This disclosure of the invention is submitted in furtherance of the constitutional purposes of the U.S. Patent Laws “to promote the progress of science and useful arts” (Article 1, Section 8).

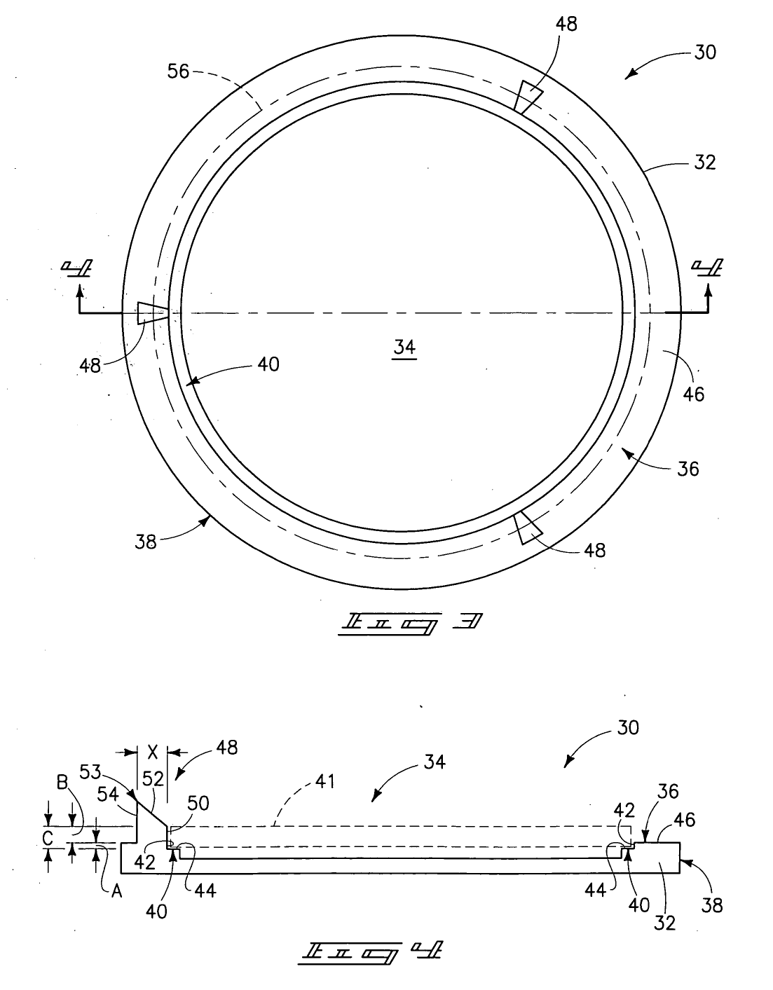

Referring initially to FIGS. 3 and 4, a substrate susceptor for receiving a substrate to be deposited upon is indicated generally with reference numeral 30. Susceptor 30 comprises a body 32 having a substrate receiving side 34 and an outermost peripheral edge 38. Substrate receiving side 34 comprises a face 36. In the depicted exemplary preferred embodiment, body 32 is entirely solid, and face 36 spans completely and continuously thereacross within the confines of outermost peripheral edge 38. An exemplary preferred material for body 32 is SiC coated graphite.

Substrate receiving side face 36 has a substrate receiving recess 40 formed therein. A recess is not required in all aspects of the invention. A substrate to be deposited upon is depicted in FIG. 4 in dashed lines, designated with numeral 41, and received within recess 40. As shown, substrate receiving recess 40 is annular, having an outer peripheral sidewall 42 and a base 44. Recess base in one implementation is preferably substantially planar. At least a portion of recess outer peripheral sidewall 42 extends perpendicularly from recess base 40, with all of recess outer peripheral sidewall 42 being shown extending perpendicularly from recess base 44. Recess 40 might be the same or different from prior art susceptor recesses, including yet-to-be developed recesses. Recess outer peripheral sidewall 42 is depicted as being straight in cross-section, and can be considered as having an elevational length A. FIG. 4 depicts the preferred elevational length A being less than the thickness of substrate 41 for which the susceptor is designed.

Face 36 can be considered as having a portion thereof which has been designated with numeral 46. In the depicted embodiment, face portion 46 is annular and received radially outward of recess 40 on body 32. At least three projections 48 extend outwardly from face portion 46, with three such projections being shown in FIG. 3. Projections 48 respectively comprise a radially inner sidewall 50 which extends outwardly from recess outer peripheral sidewall 42 to a projection upper surface 52. Projections 48 respectively have an outermost peripheral edge 54 which, in the preferred embodiment, is received radially inward of body outermost peripheral edge 38.

In the illustrated preferred embodiment, face portion 46 is substantially planar and continuous, but for projections 48. Further, all of projections 48 comprise a common shape. Further, projections 48 are equally spaced on face portion 46 from immediately adjacent of such projections. Further preferably, projections 48 number no more than 8. Accordingly, preferred exemplary embodiments include a susceptor where the projections number only any one of 3, 4, 5, 6, 7 or 8. In the depicted preferred embodiment, projections 48 are received about a circle 56 (FIG. 3) on face portion 46. Preferably, such projections collectively occupy less than 10% of the circumference of circle 56, more preferably less than 5%, and even more preferably less than 3%. One preferred reason to minimize the circumference occupation by the projections is to minimize any disruption of gas flow across the substrate, where in one example such gas flow is from one peripheral side of the substrate to another while the susceptor rotates. By way of example only, exemplary preferred maximum circumferential widths of individual projections 48 are from 0.25 cm to 1.0 cm.

Projection radially inner sidewalls 50 can be considered as having an elevational length B. In the depicted FIG. 4 embodiment, recess outer peripheral sidewall 42 and radially inner sidewall 50 have a combined elevational length C which is equal to the thickness of substrate 41 for which the susceptor is designed. Additionally, upper surface 52 has an uppermost elevation, or point, 53 which is received elevationally higher than substrate 41 for which the susceptor is designed, when susceptor 41 rests on base 44.

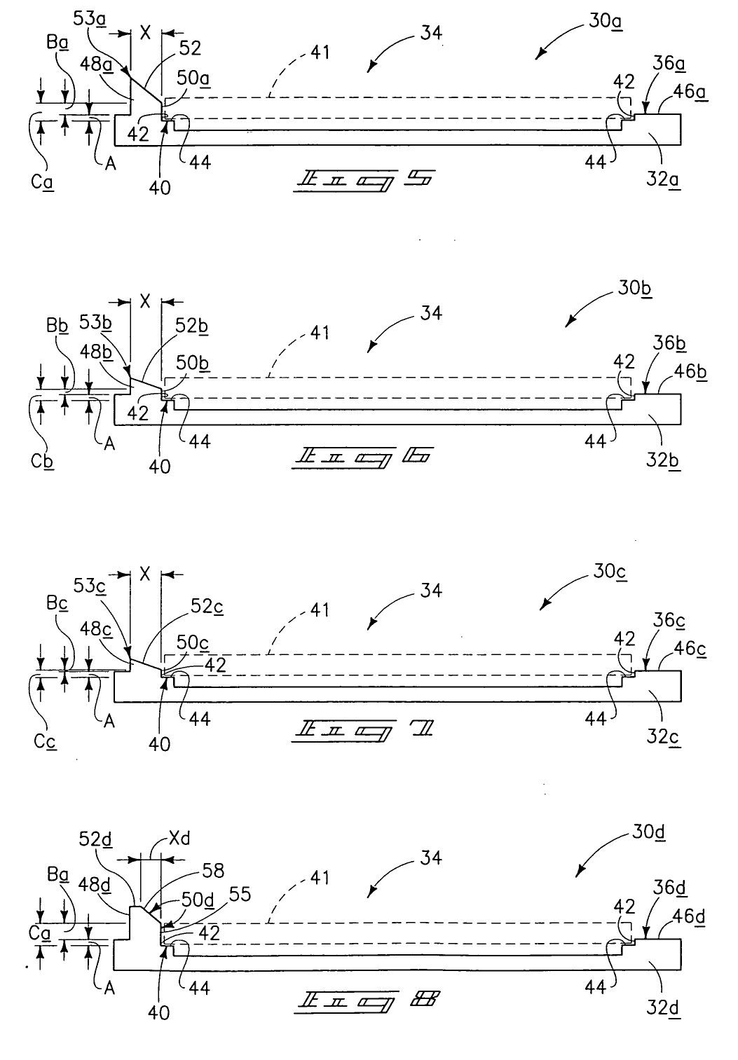

By way of example only, FIGS. 5, 6 and 7 depict alternate exemplary embodiments. Like numerals from the first described embodiment have been utilized where appropriate, with differences being indicated by the suffixes “a”, “b” and “c” in FIGS. 5, 6 and 7, respectively. FIG. 5 depicts a susceptor 30a having a projection radially inner sidewall 50a with an elevational length Ba which is less than that of FIG. 4. Accordingly, recess outer peripheral sidewall 42 and radially inner sidewall 50a have a combined elevational length Ca which is less than the thickness of substrate 41 for which the susceptor is designed.

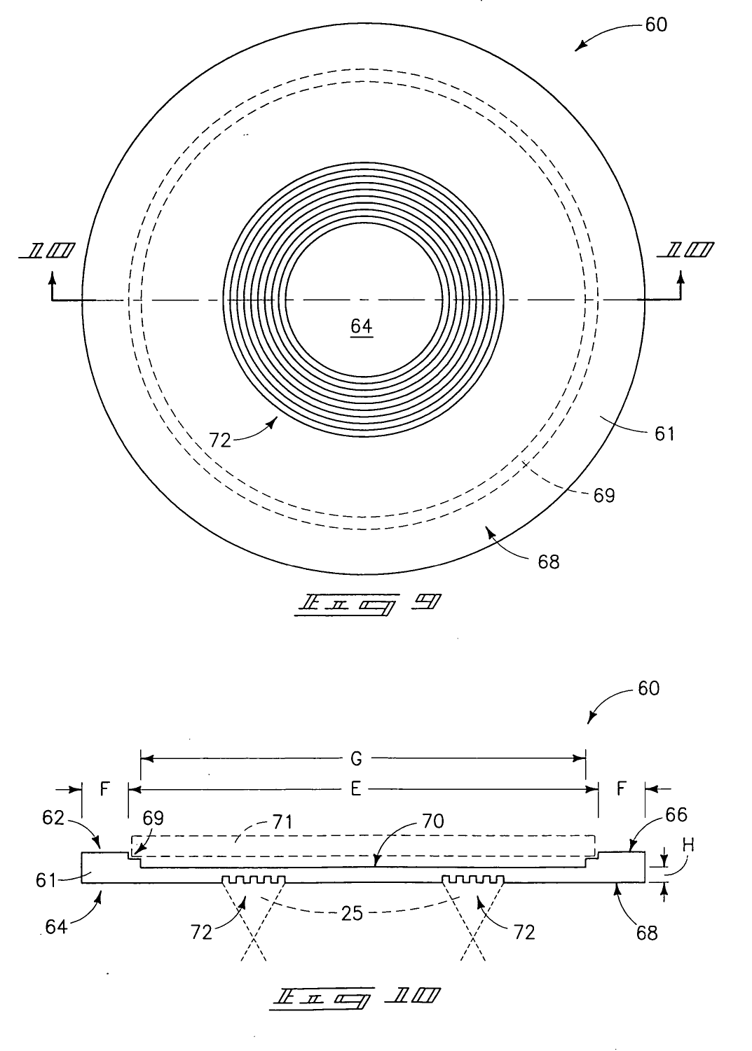

FIG. 6 illustrates a susceptor 30b also having a combined elevationally length Cb which is less than the thickness of substrate 41, and also upper surface 52b having an outermost elevation 53b which is elevationally coincident with an upper surface of substrate 41 when substrate 41 is received against recess base 44. FIG. 7 depicts a susceptor 30c having a projection upper surface 52c having an uppermost elevation 53c which is received elevationally lower than the upper surface of substrate 41 for which the susceptor is designed when substrate 41 is received against recess base 44.

Further and of course, the recess outer peripheral sidewall and the radially inner sidewall could have a combined elevational length which is greater than the thickness of the substrate for which the susceptor is designed (not shown). Further in such instance, the recess outer peripheral sidewall could have an elevational length which is less than, equal to or greater than the thickness of the substrate for which the susceptor is designed.

Referring again to FIG. 4, projection upper surface 52 is depicted as extending along a straight line in radially cross-section, although curved lines (i.e., convex or concave) are also contemplated but not preferred. In the illustrated preferred embodiment, projection upper surface 52 is angled radially downward toward substrate receiving recess 40 and along a straight line in radial cross-section, as shown. Where at least one of face portion 46 and base 44 are substantially planar, upper surface 52 is preferably angled at from 20° to 80° from the respective face portion and/or base, and more preferably at from 40° to 60°. An exemplary angle of 40° is shown in FIGS. 4 and 5 for surface 52, and also 40° for surface 52d in FIG. 8 (described below). An angle of 20° is shown in FIGS. 6 and 7 for surfaces 52b and 52c.

FIG. 8 depicts an alternate exemplary embodiment susceptor 30d. Like numerals from the first described embodiment are utilized where appropriate, with differences being indicated with the suffix “d” or with different numerals. Susceptor 30d comprises a projection 48d comprising a radially inner sidewall 50d extending outwardly from recess outer peripheral sidewall 42 to a projection upper surface 52d. At least a portion of outer peripheral sidewall 50d is angled radially downward toward substrate receiving recess 40. Specifically, recess outer peripheral sidewall 50d includes a first portion 55 extending perpendicular relative to recess base 44, and a second portion 58 extending from first portion 56 and being angled radially downward toward substrate receiving recess 40. In preferred embodiments, surfaces 52, 52a, 52b, 52c and 58 extend along a line in radial cross-section such that the surfaces have a radial extent (i.e., an x-axis dimension “X” of the angle formed by such surfaces with surface portion 46 and/or base 44) of at least 5 millimeters.

Aspects of the invention as described above are expected to enable overall better initial alignment of the substrate within the recess, as even misaligned substrates will tend toward alignment into the recess due to the ramped nature of surfaces 52, 52a, 52b, 52c and 58. Further, the raised projection radially inner sidewalls are expected to achieve better lateral retention of the substrate within the recess. However, the invention does not require achieving either of the advantages stated in this paragraph.

Further, the invention contemplates a substrate susceptor for receiving a substrate to be deposited upon, with the susceptor including a body having a substrate receiving side. The substrate receiving side comprises a face. At least three projections extend outwardly from a portion of the face. The projections respectively comprise a radially inner substrate retaining sidewall which extends outwardly to a projection upper surface. A substrate receiving recess may or may not be employed. Other preferred aspects are as described above.

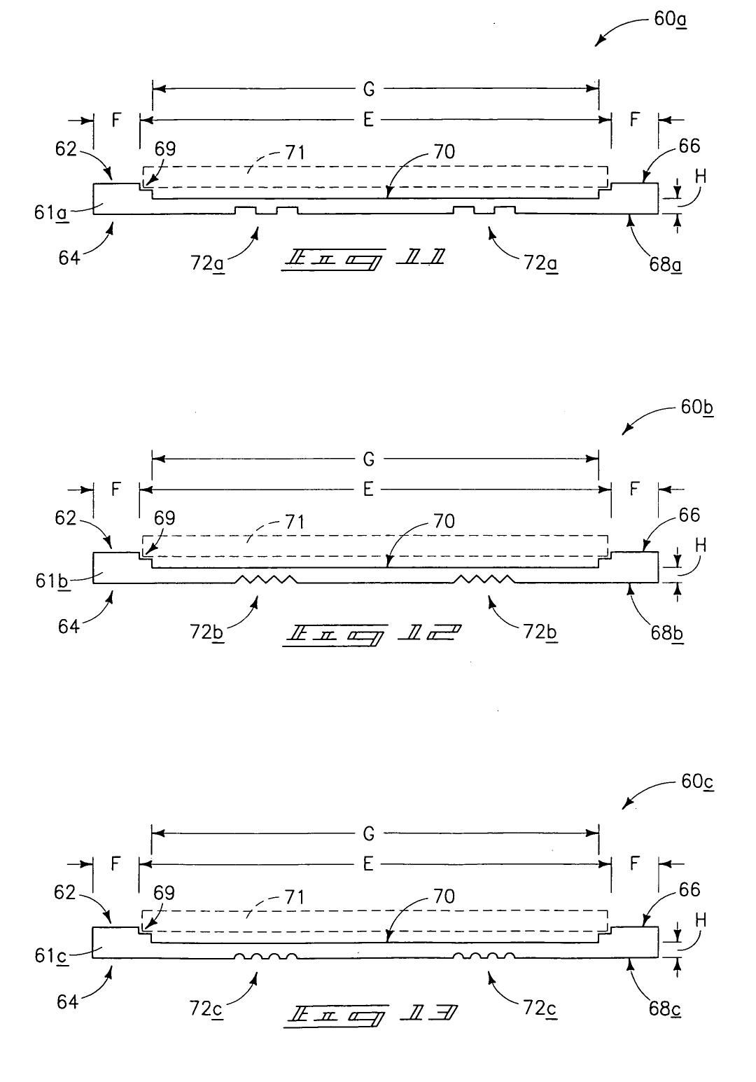

Some other implementations of aspects of the invention are initially described with reference to FIGS. 9 and 10. Such depict a substrate susceptor for receiving a substrate to be deposited upon by thermal deposition comprising back side radiant heating of the susceptor. Heating in addition to back side radiant heating is also of course contemplated, for example front side heating as depicted in FIG. 2, as well as additional or other heating whether existing or yet-to-be developed. In one preferred implementation, the substrate susceptor is adapted for receiving a substrate to be deposited upon by thermal deposition comprising back side radiant heating of the susceptor from at least two back side radiation emitting sources which form an overlapped area of back side incident radiation, for example back side overlapped areas 25 as depicted in FIG. 2.

Substrate susceptor 60 comprises a body 61 having a front substrate receiving side 62 and a back side 64. Front side 62 comprises a face 66, and back side 64 comprises a face 68. In the depicted exemplary embodiment, body 61 is entirely solid, and faces 66 and 68 span completely and continuously thereacross within the confines of an outermost peripheral edge of the body. An exemplary preferred material for body 61 is SiC coated graphite. Front side face 66 comprises a recess 69 configured for receiving a substrate 71 to be deposited upon.

Front side face 66 has an inner area E in the preferred embodiment described or defined by the peripheral edges of recess 69, and has a peripheral area F received thereabout. Front side face 66 comprises an inner area face 70 over which substrate 71 to be deposited upon is to be received. In the depicted FIGS. 9 and 10 embodiment, inner area face 70 is bounded by the inner peripheral edges of substrate recess 69, thereby spanning area G across the susceptor. In one preferred embodiment, and as depicted, inner area face 70 is defined such that substrate 71 to be deposited upon extends laterally outside inner area face 70.

The back side face comprises at least one radiation emission-lowering recess received opposite a portion of the front side inner area face over which the substrate to be deposited upon is to be received, and preferably a plurality/multiple of radiation emission-lowering recesses. In the context of this document, an “emission-lowering recess” is a recess in the back side face which has the effect of lowering heat emission to the back side of the substrate to be deposited upon which is received on the front side face. Accordingly, recesses in accordance with an aspect of the invention might modify incident radiation absorption or reflection (by way of example only) in some manner which results in less heat effecting radiation going to the back side of the substrate to be deposited upon. Such might result in one or more of better temperature uniformity across the wafer, and improved film uniformity in terms of one or more of thickness, composition and density.

FIG. 10 depicts back side face 64 comprising a multiple radiation emission-lowering recesses 72 received opposite a portion of front side inner area face 70 in the form of annular grooves. Such grooves are of a common shape and square in cross-section, as depicted. In the depicted preferred embodiment, back side face 64 is substantially planar but for said radiation emission-lowering recesses 72. Further, body 61 has a constant thickness H within at least a majority of, and within all of as shown, inner area face 70 over which substrate 71 to be deposited upon is to be received but for said radiation emission-lowering recesses 72.

In one most preferred embodiment, the radiation emission-lowering recess or recesses are received within the overlapped area of back side incident radiation (i.e., area 25 from FIG. 2), thereby lowering the emission of radiation to the substrate in the overlapped area towards more temperature uniformity. It is recognized in the above-described prior art FIG. 2 embodiment that front side incident radiation overlap occurs for which the exemplary FIG. 10 embodiment would have no likely temperature lowering effect from such front side radiation overlap. However, the surface area increasing recesses are preferably advantageously configured to reduce/lower radiation emission to substrate 71 in the overlapped area of back side incident radiation from multiple back side radiation emitting sources. The one or more radiation emission-lowering recesses 72 might encompass all, a portion of, or more than the overlapped area(s), or be received in no overlapped area regardless of the existence of such.

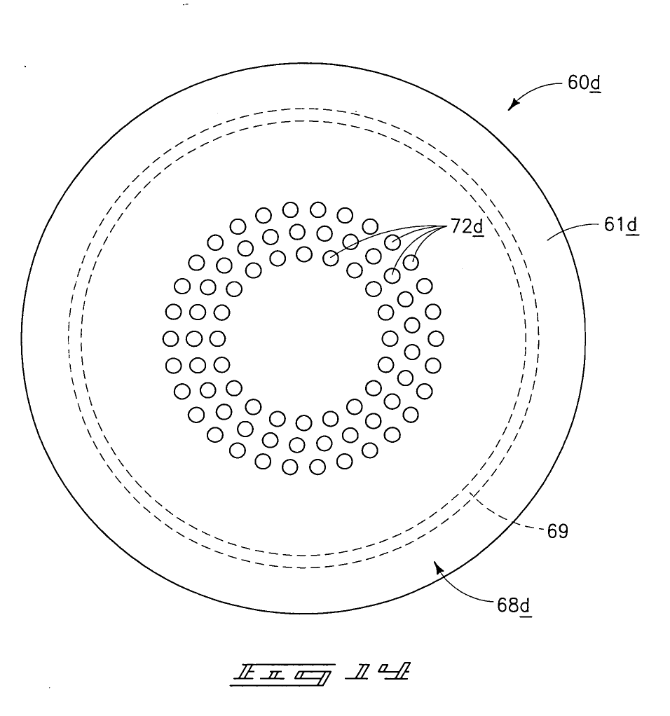

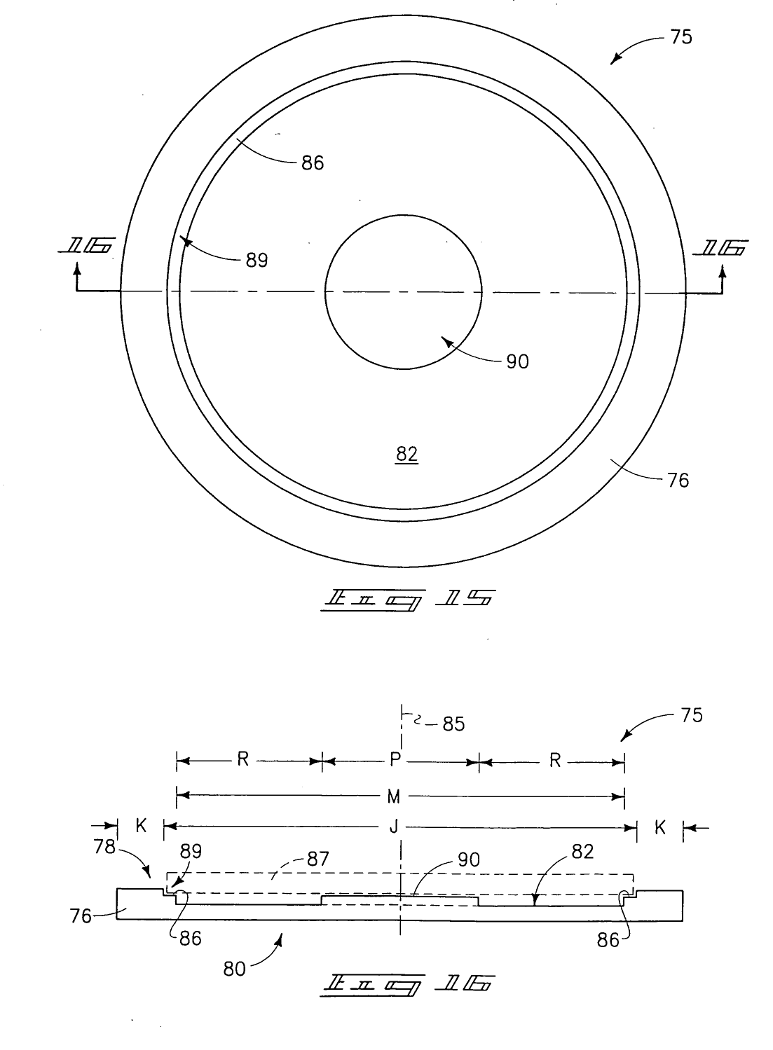

Alternate radiation emission-lowering recesses are also of course contemplated, for example and by way of example only as depicted in FIGS. 11, 12, 13 and 14. Like numerals from the FIGS. 9 and 10 embodiment are utilized where appropriate, with differences being indicated with the suffix “a”, “b” “c” and “d” in FIGS. 11, 12, 13 and 14, respectively. FIG. 11 depicts radiation emission-lowering recesses 72a of a substrate susceptor 60a which are rectangular in cross-section. FIG. 12 depicts radiation emission-lowering recesses 72b of a substrate susceptor 70b which are triangular in cross-section. FIG. 13 depicts radiation emission-lowering recesses 72c of a substrate susceptor 60c which are half-circle in shape, thereby including at least some curved portion in cross-section.

Each of the above-described FIGS. 9-13 preferred embodiments show a plurality of discrete radiation emission-lowering recesses which are formed about an annulus. By way of example only, FIG. 14 depicts a plurality of discrete half-spherical radiation emission-lowering recesses 72d formed about an annulus. Positioning other than about an annulus is also of course contemplated.

Of course, aspects of the above-described invention regarding projections can be combined with any aspect of the inventions just described regarding back side face radiation emission-lowering recesses.

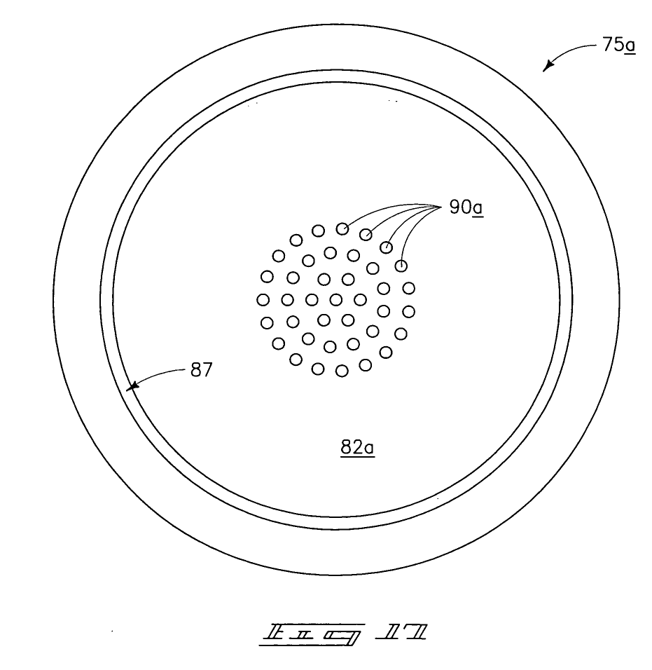

Some other implementations of aspects of the invention are described initially with reference to FIGS. 15 and 16. Aspects of these implementations comprise a substrate susceptor for receiving a substrate to be deposited upon by thermal deposition comprising susceptor heating, for example (and by way of example only) by at least one of radiant susceptor heating (i.e., as described in the prior art description) and resistive susceptor heating (i.e., for example where resistive heating elements are received within or proximate a susceptor). FIGS. 15 and 16 depict a substrate susceptor 75 comprising a body 76 having a front substrate receiving side 78 and a back side 80. Front side 78 has an inner area J and a peripheral area K received about inner area J. Front side 78 comprises an inner area face 82 which is received within and smaller than inner area J. In the depicted embodiment, inner area face 82 is encompassed within the confines of a depicted area M. Inner area face 82 has a central region P and a peripheral region R received about central region P. Central region P has a center 85. Front side inner area J has a peripheral surface 86 configured to at least in part support a substrate 87 to be deposited upon proximate a periphery of substrate 87 to space such substrate from a portion of front side inner area face 82. In the illustrated preferred embodiment, peripheral surface 86 is continuous and planar about a circle, and comprises a base of a front side substrate receiving recess 89.

Front side inner area face 82 comprises at least one central region projection 90 extending to contact substrate 87 which will be deposited upon. (In the depicted drawings, substrate 87 is shown spaced slightly from projection 90 and surface 86 only for clarity in the drawings.) In the depicted FIGS. 15 and 16 embodiment, central region projection 90 constitutes a single solid cylinder which is centered within central region P. In one preferred embodiment, single solid cylinder 90 has a radius of from 25% to 33% of the radius of substrate 87 which will be deposited upon. Regardless, in one exemplary embodiment, the single solid cylinder has a radius of at least 10 mm and in another embodiment has a radius of at least 30 mm.

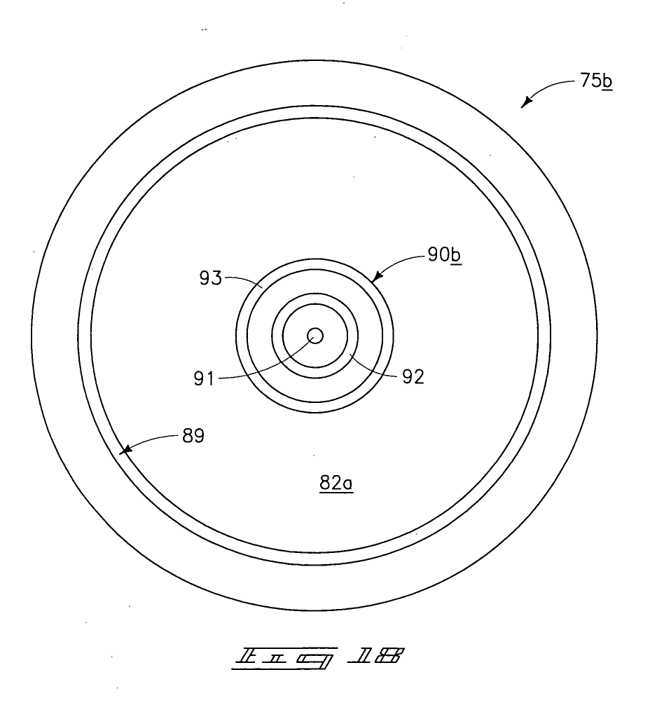

FIG. 17 depicts an alternate embodiment substrate susceptor 75a. Like numerals from the FIGS. 15 and 16 embodiment are utilized where appropriate, with differences being indicated with the suffix “a” or with different numerals. Front side inner area face 82a comprises multiple central region projections 90a extending to contact substrate 87 (not shown) which will be received for deposition in a like manner to that depicted in FIG. 16. FIG. 17 depicts the multiple central region projections 90a in the form of multiple solid cylinders.

FIG. 18 depicts a substrate susceptor 75b having multiple central region projections 90b. Like numerals from the FIGS. 15 and 16 embodiment are utilized where appropriate, with differences being indicated with the suffix “b”. In FIG. 18, central region projection 90b comprises a solid cylinder 91 and multiple rings 92 and 93 received thereabout, with two such rings being shown. The depicted projections 91, 92 and 93 are concentric about center 85 (not shown in FIG. 18) of central region P. Preferably, the illustrated projections, including rings, collectively occupy a radius of from 25% to 33% of the radius of substrate 87 which will be deposited upon. Regardless, such projections including multiple rings preferably collectively occupy a radius of at least 10 mm, and more preferably collectively occupy a radius of at least 30 mm.

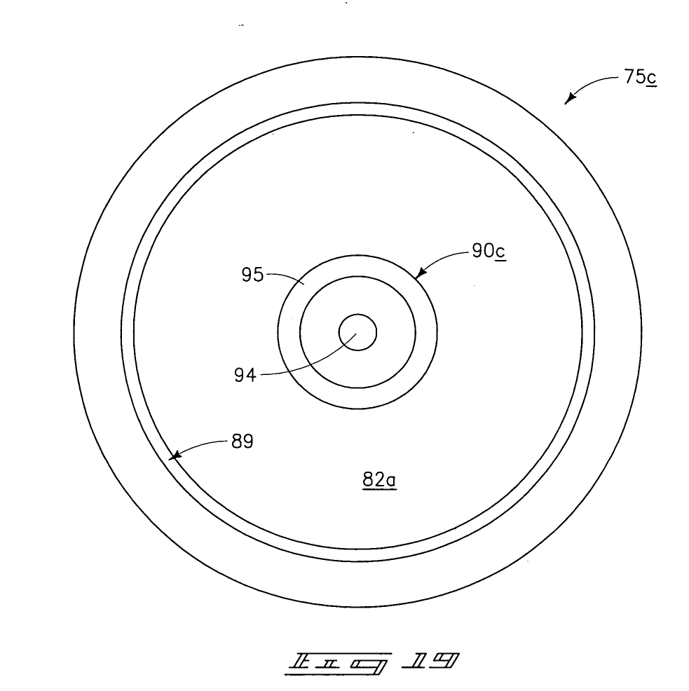

FIG. 19 depicts another exemplary embodiment. Like numerals from the FIGS. 15 and 16 embodiment are utilized where appropriate, with differences being indicated with the suffix “c”. By way of example only, FIG. 19 depicts a substrate susceptor 75c wherein at least one central region projection 90c comprises a solid cylinder 94 having only a single ring 95 received thereabout.

In one preferred implementation, and for example as described in connection with central region projections 90, 90a, 90b and 90c, the at least one central region projection is effective to raise the average temperature of the portion of substrate 87 to be deposited upon which overlies central region P during deposition upon such substrate than would otherwise occur under identical conditions in the absence of the at least one central region projection. In one preferred implementation, the substrate susceptor is adapted for receiving substrate 87 to be deposited upon by thermal deposition which creates a first region of such substrate, when overlying central region P of inner area face 82, to have an average temperature which is lower than a second region of substrate 87 immediately surrounding the first region. The central region projection increases the first region average temperature compared to the second region average temperature than would otherwise occur under identical conditions in the absence of the at least one central region projection. For example, and by way of example only, the above-described embodiments preferably and advantageously have the effect of increasing the temperature of what would otherwise be a cold spot at the center of a substrate being deposited upon.

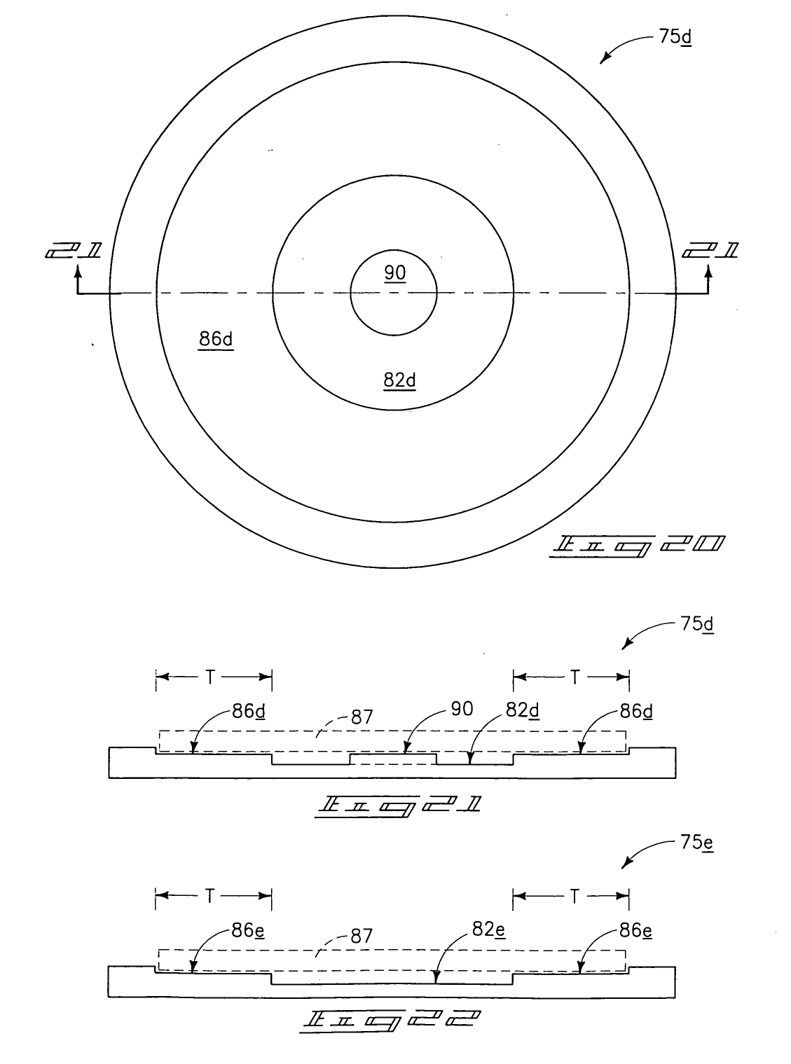

FIGS. 20 and 21 depict an alternate embodiment substrate susceptor 75d. Like numerals from the FIGS. 15 and 16 embodiment are utilized where appropriate, with differences being indicated with the suffix “d”. Peripheral surface 86d in substrate susceptor 75d extends radially inward with at least a 20 mm radial length T which is positioned to contact substrate 87 to be deposited upon. (Again in the depicted drawings, substrate 87 is shown spaced slightly from surface 86e only for clarity in the drawings.) Further preferred embodiments include radial lengths T of at least 25 mm, 30 mm and 35 mm. Further and regardless, in one preferred embodiment, peripheral surface 86d extends radially inward with at least a radial length T of from 25% to 33% of the radius of substrate 87 to be deposited upon which is positioned to contact such substrate. Of course, any of the above or other described attributes with respect to central projection(s) 90 could be employed in the FIG. 21 embodiment. Further by way of example only, the invention contemplates a peripheral surface extending radially inward with at least a 20 mm radial length of the peripheral surface being positioned to contact the substrate to be deposited upon even if no central region projection is included, for example as shown with respect to a substrate susceptor 75e in FIG. 22.

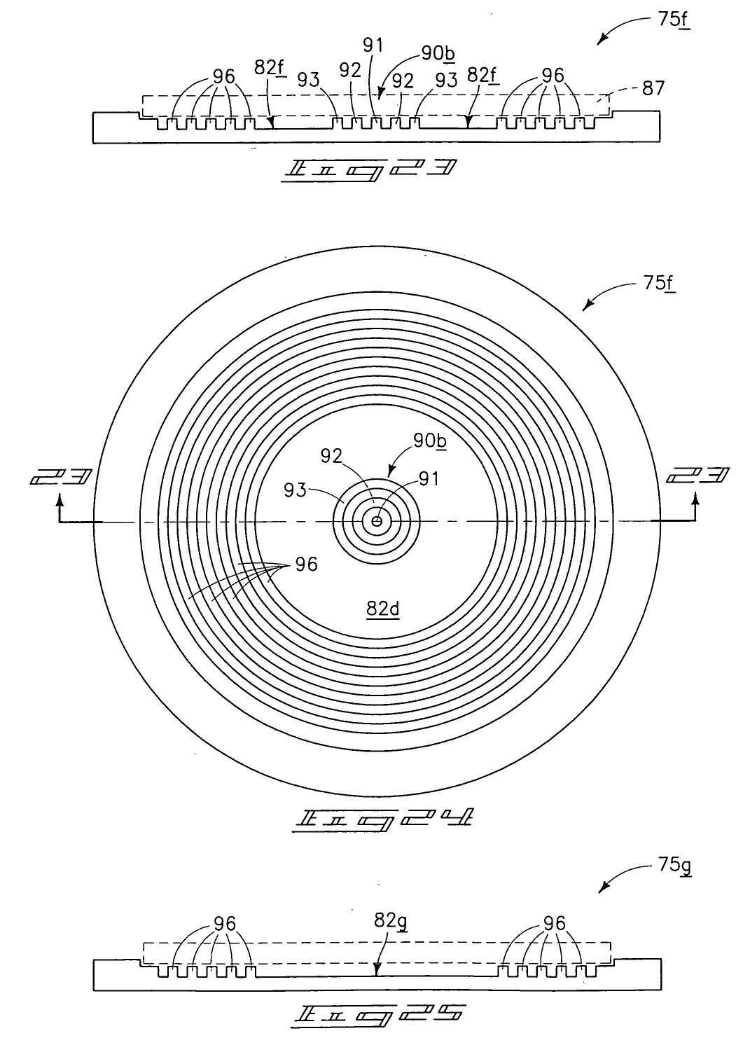

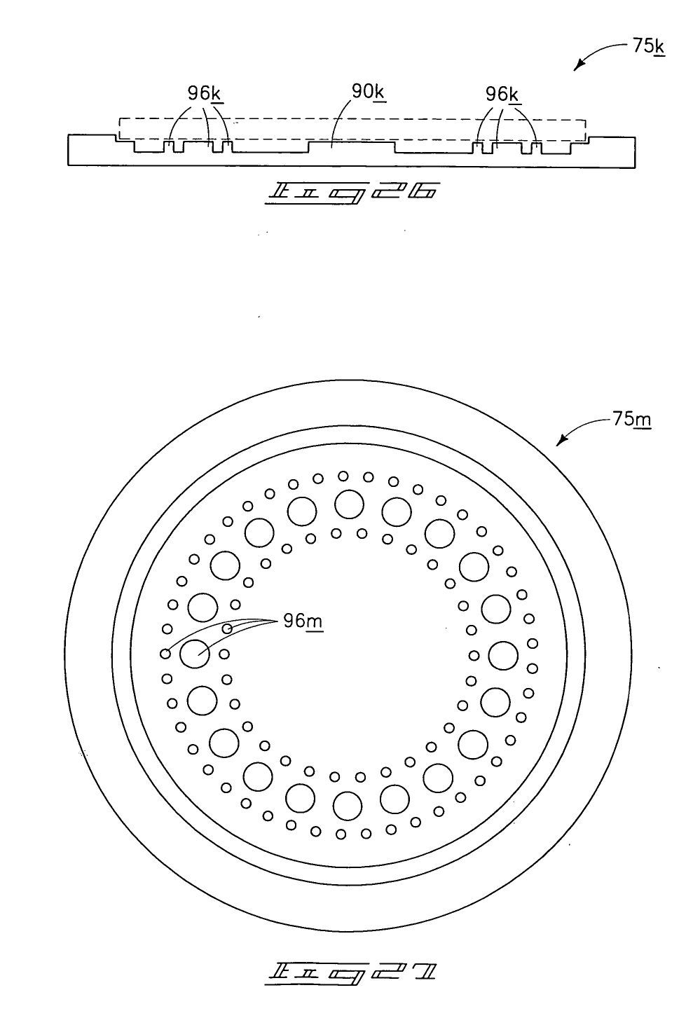

Yet another alternate exemplary embodiment in accordance with an aspect of the invention is described with reference to FIGS. 23 and 24 in connection with a substrate susceptor 75f. Like numerals from the embodiments of FIGS. 15-22 are utilized where appropriate, with differences being indicated with the suffix “f”, or with different numerals. Front side inner area face 82f comprises a plurality of projections 96 within inner area face peripheral region R extending to contact substrate 87 to be deposited upon. By way of example only, FIGS. 23 and 24 also depict central region projections 90b extending to contact substrate 87 to be deposited upon. Of course, any of the attributes described above or otherwise with respect to at least one central region projection could be employed. Further as depicted by way of example only in FIG. 25 with respect to a susceptor 75g, this aspect of the invention contemplates a plurality of projections within the inner area face peripheral regions which extend to contact the substrate to be deposited upon independent of whether there is or are any central region projection(s).

FIGS. 23-25 depict the plurality of peripheral region projections 96 as comprising rings, with such rings being concentric about center 85 of central region P (shown in FIG. 16). Such rings 96 are also depicted as being of constant width. By way of example only, FIG. 26 depicts a substrate susceptor 75k having rings 96k of at least two different widths and spacings. Of course, a plurality of projections are also contemplated which are not required to be ring-shaped (or of the same size or even shape) which, by way of example only, are shown in FIG. 27 with respect to a substrate susceptor 75m. Such depict the plurality of inner area face projections 96m as comprising multiple solid cylinders.

The projections as described above with respect to FIGS. 20-27 might be employed to increase the peripheral average temperature of the substrate where a cold spot might exist, or less than desired uniformity in such regions or across the substrate might exist.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

1-104. (canceled)

105. A substrate susceptor for receiving a substrate to be deposited upon by thermal deposition comprising susceptor heating, the susceptor comprising:
a body having a front substrate receiving side and a back side, the front side having an inner area and a peripheral area received about the inner area, the front side comprising an inner area face received within and smaller than the inner area, the inner area face having a central region and a peripheral region received about the central region, the front side inner area having a peripheral surface configured to at least in part support a substrate to be deposited upon proximate a periphery of said substrate to space said substrate from a portion of the front side inner area face, the front side inner area face comprising at least one central region projection extending to contact the substrate to be deposited upon.

106. The susceptor of claim 105 wherein the at least one central region projection comprises a solid cylinder.

107. The susceptor of claim 106 wherein the at least one central region projection comprises multiple solid cylinders.

108. The susceptor of claim 106 wherein the at least one central region projection comprises only a single solid cylinder.

109. The susceptor of claim 108 wherein the single solid cylinder is centered within the central region.

110. The susceptor of claim 109 wherein the single solid cylinder has a radius of at least 10 mm.

111. The susceptor of claim 109 wherein the single solid cylinder has a radius of at least 30 mm.

112. The susceptor of claim 109 wherein the single solid cylinder has a radius of from 25% to 33% of radius of said substrate to be deposited upon.

113. The susceptor of claim 105 wherein the at least one central region projection comprises a ring.

114. The susceptor of claim 113 wherein the ring is concentric about a center of the central region.

115. The susceptor of claim 105 wherein the at least one central region projection comprises multiple rings.

116. The susceptor of claim 115 wherein the multiple rings are concentric about a center of the central region.

117. The susceptor of claim 116 wherein the multiple rings collectively occupy a radius of at least 10 mm.

118. The susceptor of claim 116 wherein the multiple rings collectively occupy a radius of at least 30 mm.

119. The susceptor of claim 116 wherein the multiple rings collectively occupy a radius of from 25% to 33% of radius of said substrate to be deposited upon.

120. The susceptor of claim 105 wherein the front side inner area face comprises multiple central region projections extending to contact the substrate to be deposited upon.

121. The susceptor of claim 120 wherein the at least one central region projection comprises a solid cylinder and at least one ring received thereabout.

122. The susceptor of claim 121 wherein the at least one central region projection comprises a solid cylinder and only a single ring received thereabout.

123. The susceptor of claim 121 wherein the at least one central region projection comprises a solid cylinder and multiple rings received thereabout.

124. The susceptor of claim 123 wherein the at least one central region projection comprises a solid cylinder and only two rings received thereabout.

125. The susceptor of claim 105 wherein the at least one central region projection is effective to raise average temperature of; a portion of said substrate overlying the central region during deposition upon said substrate than would otherwise occur under identical conditions in the absence of the at least one central region projection.

126. The susceptor of claim 105 being adapted for receiving a substrate to be deposited upon by thermal deposition which creates a first region of said substrate when overlying the central region of the inner area face to have an average temperature which is lower than a second region of said substrate immediately surrounding the first region, with the central region projection increasing the first region average temperature compared to the second region average temperature than would otherwise occur under identical conditions in the absence of the at least one central region projection.

127. The susceptor of claim 105 wherein the peripheral surface is continuous and planar about a circle.

128. The susceptor of claim 105 wherein the peripheral surface extends radially inward with at least a 20 mm radial length of the peripheral surface being positioned to contact the substrate to be deposited upon.

129. The susceptor of claim 105 wherein the front side inner area face comprises a plurality of projections within the inner area face peripheral region extending to contact the substrate to be deposited upon.

130. The susceptor of claim 129 wherein the plurality of peripheral region projections comprise rings.

131. The susceptor of claim 130 wherein the rings are of constant width.

132. The susceptor of claim 130 wherein the rings are of at least two different widths.

133. The susceptor of claim 130 wherein the rings are concentric about a center of the central region.

134. The susceptor of claim 105 wherein the front side face comprises a substrate receiving recess comprising the peripheral surface.

135. A substrate susceptor for receiving a substrate to be deposited upon by thermal deposition comprising susceptor heating, the susceptor comprising:
a body having a front substrate receiving side and a back side, the front side having an inner area and a peripheral area received about the inner area, the front side comprising an inner area face received within and smaller than the inner area, the inner area face having a central region and a peripheral region received about the central region, the front side inner area having a peripheral surface configured to at least in part support a substrate to be deposited upon proximate a periphery of said substrate to space said substrate from a portion of the front side inner area face, the peripheral surface extending radially inward with at least a 20 mm radial length of the peripheral surface being positioned to contact a substrate to be deposited upon.

136. The susceptor of claim 135 wherein at least a 25 mm radial length of the peripheral surface is positioned to contact the substrate to be deposited upon.

137. The susceptor of claim 135 wherein at least a 30 mm radial length of the peripheral surface is positioned to contact the substrate to be deposited upon.

138. The susceptor of claim 135 wherein at least a 35 mm radial length of the peripheral surface is positioned to contact the substrate to be deposited upon.

139. The susceptor of claim 135 wherein the peripheral surface extends radially inward with at least a radial length of from 25% to 33% of radius of said substrate to be deposited upon of the peripheral surface being positioned to contact the substrate to be deposited upon.

140. A substrate susceptor for receiving a substrate to be deposited upon by thermal deposition comprising susceptor heating, the susceptor comprising:
a body having a front substrate receiving side and a back side, the front side having an inner area and a peripheral area received about the inner area, the front side comprising an inner area face received within and smaller than the inner area, the inner area face having a central region and a peripheral region received about the central region, the front side inner area having a peripheral surface configured to at least in part support a substrate to be deposited upon proximate a periphery of said substrate to space said substrate from a portion of the front side inner area face; and
the front side inner area face comprising a plurality of projections within the inner area face peripheral region extending to contact the substrate to be deposited upon.

141. The susceptor of claim 140 wherein the plurality of peripheral region projections comprise rings.

142. The susceptor of claim 141 wherein the rings are of constant width.

143. The susceptor of claim 141 wherein the rings are of at least two different widths.

144. The susceptor of claim 141 wherein the rings are concentric about a center of the central region.

145. The susceptor of claim 144 wherein the rings are of constant width.

146. The susceptor of claim 140 wherein the plurality of inner area face projections comprise multiple solid cylinders.

147. The susceptor of claim 140 wherein the front side inner area face comprises a central region ring projection extending to contact the substrate to be deposited upon.

148. The susceptor of claim 147 wherein the ring is concentric about a center of the central region.

149. The susceptor of claim 140 wherein the front side inner area face comprises multiple central region projections extending to contact the substrate to be deposited upon.

150. The susceptor of claim 149 wherein the multiple central region projections comprise a solid cylinder and at least one ring received thereabout.

151. The susceptor of claim 150 wherein the multiple central region projections comprise a solid cylinder and only a single ring received thereabout.

152. The susceptor of claim 150 wherein the multiple central region projections comprise a solid cylinder and multiple rings received thereabout.

153. The susceptor of claim 152 wherein the at least one central region projection comprises a solid cylinder and only two rings received thereabout.
